(19) United States
(12) Patent Application Publication
(10) Pub. No.: US 2026/0201177 A1
(43) Pub. Date: Jul. 16, 2026

(54) HYDROPHOBIC AND OLEOPHOBIC FILM LAYER, AND METHOD FOR PREPARING THE SAME

(71) Applicant: JIANGSU FAVORED NANOTECHNOLOGY CO., LTD., Wuxi (CN)

(72) Inventor: Jian ZONG, Wuxi (CN)

(73) Assignee: JIANGSU FAVORED NANOTECHNOLOGY CO., LTD., Wuxi (CN)

(21) Appl. No.: 19/132,465

(22) PCT Filed: Nov. 2, 2023
(86) PCT No.: PCT/CN2023/129205

§ 371 Date: May 23, 2025

(30) Foreign Application Priority Data
Nov. 25, 2022 (CN) 202211513302.X

(51) Int. Cl. C09D 5/16; B05D 1/00; C08F 20/24; C09D 133/16

(52) U.S. Cl. CPC C09D 5/1668; B05D 1/60; C08F 20/24; C09D 133/16

(57) ABSTRACT

The present disclosure provides a hydrophobic and oleophobic film layer and a method for preparing the hydrophobic and oleophobic film layer. The hydrophobic and oleophobic film layer is prepared from a perfluoropolyether monomer containing (meth)acrylate group(s) by plasma chemical vapor deposition.

### CROSS-REFERENCE TO RELATED APPLICATIONS

This application claims the priority to Chinese Patent Application No. 202211513302.X, filed on Nov. 25, 2022, and entitled “HYDROPHOBIC AND OLEOPHOBIC FILM LAYER, AND PREPARATION METHOD THEREFOR”, the contents of which are incorporated herein by reference in their entirety.

### TECHNICAL FIELD

The present disclosure generally relates to surface modification field, and more particularly, to a hydrophobic and oleophobic film layer and a preparation method therefor.

### BACKGROUND

Hydrophobic and oleophobic film layers can be applied to substrates for surface self-cleaning, anti-fouling and corrosion protection. Preparation of oleophobic surfaces is more challenging than preparation of hydrophobic surfaces because the surface tension of water (72 mN/m) is much higher than that of oil (25-40 mN/m). Oil can diffuse on almost any fluorine-free substrate. Only when the surface energy of the substrate or coating is lower than the surface energy of the oil, the substrate or coating exhibits varying degrees of oleophobicity. Therefore, fluorocarbon groups (—CF₂ and —CF₃) may be used for preparing oleophobic surfaces, as they reduce the material's surface tension more effectively than hydrocarbons.

Long-chain perfluoroalkyl compounds (CₙF₂ₙ₊₁—R, n≥7, LCPFAs) are widely used in the preparation of hydrophobic and oleophobic surfaces. However, due to the bioaccumulation and toxicity to the environment, humans and wildlife, as well as the resistance to degradation in nature, LCPFAs have been phased out of production and applications, and the EU POPs regulation mandates a ban on the use of Perfluorooctanoic Acid (PFOA) and Perfluorooctane Sulfonic Acid (PFOS) and their derivatives.

Perfluoropolyethers (PFPEs) can serve as alternatives to long-chain perfluoroalkyl substances, have fluorinated units in the main chain interrupted by oxygen, and avoid environmental issues caused by long fluorocarbon chain alkyl compounds. Additionally, their surface energy can be as low as 10-14 mN/m. Therefore, a film layer with excellent hydrophobic and oleophobic performance may be prepared based on the modification of perfluoropolyether chain segments.

### SUMMARY

Embodiments of the present disclosure provide a hydrophobic and oleophobic film layer which is a plasma polymerization film layer formed by contacting a substrate with a plasma of a monomer having a structure of formula (1),

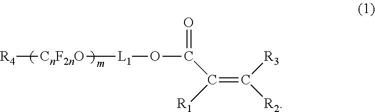

In formula (1), R₁, R₂ and R³ are respectively and independently selected from a C₁-C₄ hydrocarbon group or a hydrogen atom, and R⁴ is selected from a C₁-C₄ perfluorinated alkyl group or a fluorine atom.

In formula (1), L₁ is a linking group; m is an integer greater than or equal to 1; and each n in the m number of repeating units is respectively and independently selected from integers greater than or equal to 1.

According to some embodiments, in formula (1), the R₁, R₂ and R³ are respectively and independently selected from a methyl group or a hydrogen atom.

According to some embodiments, in formula (1), the R₁ is a methyl group, and the R₂ and R₃ are hydrogen atoms.

According to some embodiments, a weight-average molecular weight of the monomer having the structure of formula (1) is greater than or equal to 500.

According to some embodiments, the weight-average molecular weight of the monomer having the structure of formula (1) is greater than or equal to 1000.

According to some embodiments, in formula (1), the L₁ is selected from a substituted C₁-C₄ alkylene group or an unsubstituted C₁-C₄ alkylene group.

According to some embodiments, a substituent of the substituted C₁-C₄ alkylene group includes one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen.

According to some embodiments, in formula (1), the L₁ is a perfluorinated alkylene group.

According to some embodiments, the monomer of formula (1) has a structure of formula (2),

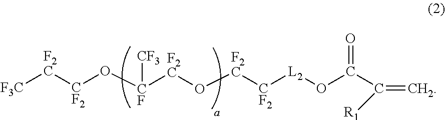

In formula (2), a is an integer greater than or equal to 1; and L₂ is selected from a connecting bond, a substituted methylene group or an unsubstituted methylene group, or a substituted ethylene group or an unsubstituted ethylene group.

According to some embodiments, the monomer of formula (1) has a structure of formula (3),

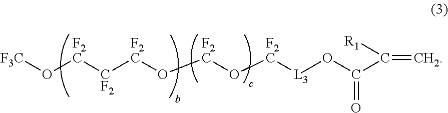

In formula (3), b is an integer greater than or equal to 1, c is an integer greater than or equal to 1, and L₃ is selected from a connecting bond, or a substituted C₁-C₃ alkylene group or an unsubstituted C₁-C₃ alkylene group.

According to some embodiments, the monomer of formula (1) has a structure of formula (4),

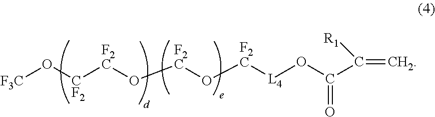

In formula (4), d is an integer greater than or equal to 1, e is an integer greater than or equal to 1, and La is selected from a connecting bond, or a substituted C₁-C₃ alkylene group or an unsubstituted C₁-C₃ alkylene group.

According to some embodiments, the monomer of formula (1) has a structure of formula (5),

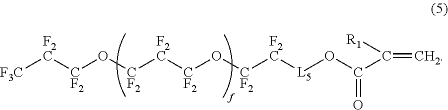

In formula (5), f is an integer greater than or equal to 1; and L₅ is selected from a connecting bond, a substituted methylene group or an unsubstituted methylene group, or a substituted ethylene group or an unsubstituted ethylene group.

According to some embodiments, a water contact angle of the hydrophobic and oleophobic film layer is greater than or equal to 110°, and an n-hexadecane contact angle of the hydrophobic and oleophobic film layer is greater than or equal to 65°.

Embodiments of the present disclosure also provide a method for preparing the hydrophobic and oleophobic film layer according to any one of aforementioned embodiments. The method includes: placing a substrate in a plasma reaction chamber; and dissolving and then adding the monomer having the structure of formula (1), a fluorine-containing solvent and a polymerization inhibitor into a monomer tank, vaporizing and then introducing the monomer into the plasma reaction chamber, turning on a plasma discharge, and forming the hydrophobic and oleophobic film layer on a surface of the substrate from the monomer through chemical vapor deposition.

According to some embodiments, a weight ratio of the monomer to the fluorine-containing solvent ranges from 1:9 to 9:1.

According to some embodiments, the fluorine-containing solvent is a fluorocarbon solvent, and the fluorocarbon solvent comprises one or more selected from a group consisting of: methyl perfluorobutyl ether, ethyl perfluorobutyl ether, 3-methoxyperfluorohexane, perfluorobutyl ethyl propyl ether, perfluoropolyether oil, hexafluoropropylene oxide dimer, hexafluoropropylene oxide trimer, perfluorotriethylamine, perfluorotripropylamine, perfluorotributylamine, 3M electronic fluorinated liquid 7100, 3M electronic fluorinated liquid 7200, 3M electronic fluorinated liquid 7300, 3M electronic fluorinated liquid 7500, and 3M electronic fluorinated liquid 7700.

According to some embodiments, a mass of the polymerization inhibitor ranges from 0.1% to 1% of a mass of the monomer.

According to some embodiments, the polymerization inhibitor comprises one or more selected from a group consisting of: hydroquinone, p-benzoquinone, methyl hydroquinone, p-hydroxyanisole, 2-tert-butylhydroquinone, 2,5-di-tert-butylhydroquinone, and 2,6-di-tert-butyl-p-cresol.

According to some embodiments, the gas vaporized from the monomer is introduced into the plasma reaction chamber at a flow rate ranging from 10 μL/min to 2000 μL/min.

According to some embodiments, the plasma discharge is a continuous discharge, a discharge power ranges from 10W to 300W, and a discharge duration time ranges from 60s to 36000s.

According to some embodiments, the plasma discharge is a pulse discharge, a discharge power ranges from 10W to 400W, a pulse duty cycle ranges from 0.1% to 80%, a pulse frequency ranges from 10 Hz to 500 Hz, and a discharge duration time ranges from 200 s to 36000 s.

According to some embodiments, the method further includes: before the chemical vapor deposition, vacuumizing to get a vacuum degree ranging from 10 mTorr to 200 mTorr, introducing one or more gases selected from a group consisting of He, Ar, and O₂, and turning on a plasma discharge to pretreat the substrate.

According to some embodiments, the plasma discharge includes: electrodeless discharge, single-electrode discharge, dual-electrode discharge, or multi-electrode discharge.

Embodiments of the present disclosure also provide a device, and at least a part of a surface of the device is provided with the hydrophobic and oleophobic film layer according to any one of aforementioned embodiments.

Embodiments of the present disclosure may provide following advantages over conventional technology.

In embodiments of the present disclosure, the hydrophobic and oleophobic film layer is prepared from a perfluoropolyether monomer containing (meth)acrylate group(s) through plasma chemical vapor deposition, a water contact angle of the hydrophobic and oleophobic film layer is greater than or equal to 110°, and an n-hexadecane contact angle of the hydrophobic and oleophobic film layer is greater than or equal to 65°.

### DETAILED DESCRIPTION

Embodiments of the present disclosure are described in detail below, and the description is exemplary, is intended only for the purpose of explaining the present disclosure, and should not to be construed as a limitation of the present disclosure.

In order to realize hydrophobic and oleophobic performance of a surface of a substrate, a device and the like, and without creating environmental problems, embodiments of the present disclosure provide a hydrophobic and oleophobic film layer which is a plasma polymerization coating formed by contacting a substrate with a plasma of a monomer having a structure of formula (1),

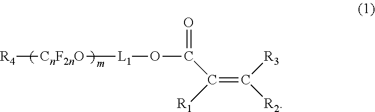

In formula (1), R₁, R₂ and R³ are respectively and independently selected from a C₁-C₄ hydrocarbon group or a hydrogen atom; R₄ is selected from a C₁-C₄ perfluorinated alkyl group or a fluorine atom; L₁ is a linking group; m is an integer greater than or equal to 1; and each n in the m number of repeating units is respectively and independently selected from integers greater than or equal to 1.

The inventor has found that the hydrophobic and oleophobic film layer formed from the monomer having the structure of formula (1) through plasma chemical vapor deposition has excellent hydrophobic and oleophobic performance. It is inferred that the reason may be that one end of the monomer is a perfluoropolyether group and the other end is an acrylate structure, after plasma polymerization, the perfluoropolyether group becomes a side chain, and the fluorocarbon groups (—CF₂ and —CF₃) gather on the surface of the film layer, so that the film layer has a low surface energy and thus has excellent hydrophobic and oleophobic properties.

According to some embodiments of the present disclosure, in formula (1), the R₁, R₂, and R³ are respectively and independently selected from a methyl group or a hydrogen atom.

According to some embodiments, the R₁ is a methyl group, and the R₂ and R₃ are hydrogen atoms.

According to some embodiments of the present disclosure, a weight-average molecular weight of the monomer having the structure of formula (1) is greater than or equal to 500, specifically being such as 500, 800, 1000, 2000, 3000, 5000, etc. According to some embodiments, the weight-average molecular weight of the monomer having the structure of formula (1) is greater than or equal to 1000, specifically being such as 1000, 2000, 3000, 4000, 5000, etc.

According to some embodiments of the present disclosure, in formula (1), the L₁ is selected from a substituted C₁-C₄ alkylene group or an unsubstituted C₁-C₄ alkylene group.

According to some embodiments of the present disclosure, a substituent of the substituted C₁-C₄ alkylene group includes one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen. According to some embodiments, the L₁ is a perfluorinated alkylene group with a straight chain or branched chain(s). According to some embodiments, the L₁ is a perfluorinated alkylene group.

According to some embodiments of the present disclosure, the perfluoropolyether chain segment includes a K-type structure, and the monomer of formula (1) has a structure of formula (2),

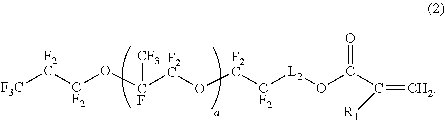

In formula (2), a is an integer greater than or equal to 1; and Lz is selected from a connecting bond, a substituted methylene group or an unsubstituted methylene group, or a substituted ethylene group or an unsubstituted ethylene group. The substituent may include one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen.

According to some embodiments of the present disclosure, the perfluoropolyether chain segment includes a Y-type structure, and the monomer of formula (1) has a structure of formula (3),

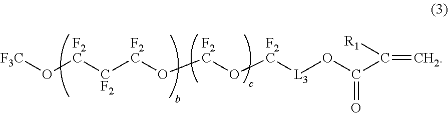

In formula (3), b is an integer greater than or equal to 1, c is an integer greater than or equal to 1, and L₃ is selected from a connecting bond, or a substituted C₁-C₃ alkylene group or an unsubstituted C₁-C₃ alkylene group. The substituent may include one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen.

According to some embodiments of the present disclosure, the perfluoropolyether chain segment includes a Z-type structure, and the monomer of formula (1) has a structure of formula (4),

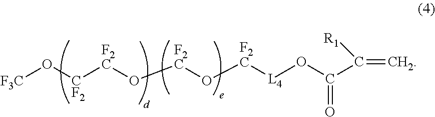

In formula (4), d is an integer greater than or equal to 1, e is an integer greater than or equal to 1, and La is selected from a connecting bond, or a substituted C₁-C₃ alkylene group or an unsubstituted C₁-C₃ alkylene group. The substituent may include one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen.

According to some embodiments of the present disclosure, the perfluoropolyether chain segment includes a D-type structure, and the monomer of formula (1) has a structure of formula (5),

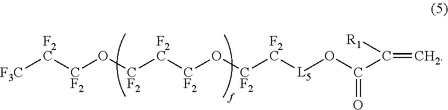

In formula (5), f is an integer greater than or equal to 1, and L₅ is selected from a connecting bond, a substituted methylene group or an unsubstituted methylene group, or a substituted ethylene group or an unsubstituted ethylene group. The substituent may include one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen.

According to some embodiments of the present disclosure, in formula (2) to formula (5), R₁ is a methyl group.

According to some embodiments of the present disclosure, a water contact angle of the hydrophobic and oleophobic film layer is greater than or equal to 110°, and an n-hexadecane contact angle of the hydrophobic and oleophobic film layer is greater than or equal to 65°.

According to some embodiments of the present disclosure, a water contact angle of the hydrophobic and oleophobic film layer is greater than or equal to 120°, and an n-hexadecane contact angle of the hydrophobic and oleophobic film layer is greater than or equal to 70°.

Some embodiments of the present disclosure also provide a device, and at least a part of a surface of the device is provided with any of the aforementioned hydrophobic and oleophobic film layer. According to some embodiments, the entire surface of the device is provided with the hydrophobic and oleophobic film layer for achieving a hydrophobic and oleophobic effect.

According to some embodiments of the present disclosure, the device includes an electrical assembly, an optical instrument, an electronic or electrical component, and the like.

Embodiments of the present disclosure also provide a method for preparing any of the aforementioned hydrophobic and oleophobic film layer. The method includes: placing a substrate in a plasma reaction chamber; and dissolving and then adding the monomer having the structure of formula (1), a fluorine-containing solvent and a polymerization inhibitor into a monomer tank, heating the monomer tank to vaporize the monomer and then introducing the monomer into the plasma reaction chamber, turning on a plasma discharge, and forming the hydrophobic and oleophobic film layer on a surface of the substrate from the plasma of the monomer through chemical vapor deposition.

According to some embodiments of the present disclosure, since the monomer having the structure of formula (1) has a relatively high molecular weight and certain viscosity, a fluorine-containing solvent is added to ensure smooth introduction of the monomer into the plasma reaction chamber. According to some embodiments, the fluorine-containing solvent is a fluorocarbon solvent. According to some embodiments, the fluorocarbon solvent includes one or more selected from a group consisting of: methyl perfluorobutyl ether, ethyl perfluorobutyl ether, 3-methoxyperfluorohexane, perfluorobutyl ethyl propyl ether, perfluoropolyether oil, hexafluoropropylene oxide dimer, hexafluoropropylene oxide trimer, perfluorotriethylamine, perfluorotripropylamine, perfluorotributylamine, 3M electronic fluorinated liquid 7100, 3M electronic fluorinated liquid 7200, 3M electronic fluorinated liquid 7300, 3M electronic fluorinated liquid 7500, and 3M electronic fluorinated liquid 7700.

According to some embodiments of the present disclosure, a weight ratio of the monomer to the fluorine-containing solvent ranges from 1:9 to 9:1, specifically being such as 1:9, 1:8, 1:7, 1:6, 1:5, 1:4, 1:3, 3:7, 1:2, 1:1, 2:1, 7:3, 3:1, 4:1, 5:1, 6:1, 7:1, 8:1, 9:1, etc.

According to some embodiments of the present disclosure, in order to prevent polymerization of the monomer having the structure of formula (1) during beating/vaporization, polymerization inhibitor is added to prevent polymerization and to avoid forming a polymer in the monomer tank. According to some embodiments, the polymerization inhibitor includes one or more selected from a group consisting of: hydroquinone, p-benzoquinone, methyl hydroquinone, p-hydroxyanisole, 2-tert-butylhydroquinone, 2,5-di-tert-butylhydroquinone, and 2,6-di-tert-butyl-p-cresol.

According to some embodiments of the present disclosure, a mass of the polymerization inhibitor ranges from 0.1% to 1% of a mass of the monomer, specifically being such as 0.1%, 0.2%, 0.3%, 0.4%, 0.5%, 0.6%, 0.7%, 0.8%, 0.9%, 1%, etc.

According to some embodiments of the present disclosure, the flow rate of the gas introduced from the monomer tank after vaporization of the monomer into the plasma reaction chamber ranges from 10 μL/min to 2000 μL/min, specifically being such as 10 μL/min, 100 μL/min, 120 μL/min, 150 μL/min, 180 μL/min, 500 μL/min, 1000 μL/min, 1500 μL/min, 2000 μL/min, etc.

According to some embodiments of the present disclosure, during the plasma polymerization process, a temperature of the reaction chamber ranges from 30° C. to 60° C., specifically being such as 30° C., 40° C., 50° C., 55° C., 60° C., etc.

According to some embodiments of the present disclosure, the plasma discharge is a continuous discharge, and a discharge power ranges from 10W to 300W, specifically being such as 10W, 50W, 100W, 200W, 300W, etc. A discharge duration time ranges from 60 s to 36000 s, specifically being such as 60 s, 360 s, 1200 s, 2400 s, 3600 s, 7200 s, 36000 s, etc.

According to some embodiments of the present disclosure, the plasma discharge is a pulse discharge, and the discharge power ranges from 10W to 400W, specifically being such as 10W, 50W, 100W, 180W, 200W, 300W, 400W, etc. A pulse duty cycle ranges from 0.1% to 80%, specifically being such as 0.1%, 1%, 10%, 25%, 35%, 50%, 60%, 70%, 80%, etc. A pulse frequency ranges from 10 Hz to 500 Hz, specifically being such as 10 Hz, 100 Hz, 200 Hz, 250 Hz, 300 Hz, 500 Hz, etc. A discharge duration time ranges from 200 s to 36000 s, specifically being such as 200 s, 360 s, 1200 s, 2400 s, 3600 s, 7200 s, 36000 s, etc.

According to some embodiments of the present disclosure, before the chemical vapor deposition, it is vacuumized to get a vacuum degree range from 10 mTorr to 200 mTorr, one or more gases selected from a group consisting of He, Ar, and O₂ are introduced, and a plasma discharge is turned on to pretreat the substrate.

According to some embodiments of the present disclosure, during pretreating the substrate, the plasma discharge is a continuous discharge, and a discharge power ranges from 50W to 600W, specifically being such as 50W, 100W, 120W, 200W, 300W, 400W, 600W, etc. A discharge duration time ranges from 60 s to 2400 s, specifically being such as 60 s, 360 s, 600 s, 1200 s, 1800 s, 2400 s, etc.

According to some embodiments of the present disclosure, during pretreating the substrate, the plasma discharge is a pulse discharge, and the discharge power ranges from 10W to 500W, specifically being such as 10W, 50W, 100W, 180W, 200W, 300W, 500W, etc. A pulse duty cycle ranges from 0.1% to 80%, specifically being such as 0.1%, 1%, 10%, 25%, 35%, 50%, 60%, 70%, 80%, etc. A pulse frequency ranges from 10 Hz to 500 Hz, specifically being such as 10 Hz, 100 Hz, 200 Hz, 250 Hz, 300 Hz, 500 Hz, etc. A discharge duration time ranges from 60 s to 2400 s, specifically being such as 60 s, 360 s, 600 s, 1200 s, 1800 s, 2400 s, etc.

According to some embodiments of the present disclosure, in the pretreatment, the plasma discharge includes: electrodeless discharge, single-electrode discharge, dual-electrode discharge, or multi-electrode discharge. According to some embodiments, the electrodeless discharge includes: radio frequency inductively coupled discharge, microwave discharge, and the like. According to some embodiments, the single-electrode discharge includes: corona discharge, plasma jet generated by unipolar discharge, and the like. According to some embodiments, the dual-electrode discharge includes: dielectric barrier discharge, radio frequency glow discharge with bare electrodes, and the like. According to some embodiments, the multi-electrode discharge includes: discharge utilizing a floating electrode as a third electrode, and the like.

The present disclosure is further described in the following specific embodiments.

### EMBODIMENT

### Description of Test Method

Water contact angle of the hydrophobic and oleophobic film layer: it was tested according to GB/T 30447-2013 standard.

Oil contact angle of the hydrophobic and oleophobic film layer: the n-hexadecane contact angle of the hydrophobic and oleophobic film layer was tested by SDC-100 standard contact angle measuring instrument.

### Embodiment 1

A Si sheet serving as a substrate was placed on a substrate holder in a plasma chamber, the chamber was vacuumized to reach a pressure of 20 mTorr, helium gas was introduced at a flow rate of 100 sccm, and a temperature of the chamber was 50° C.

A pressure in the chamber was maintained at 20 m Torr, the flow rate of helium gas was maintained at 100 sccm, and a plasma continuous discharge was turned on to pretreat the substrate. The discharge power was 100 W, and the discharge duration time was 600 s.

Thereafter, a homogeneous solution was prepared by mixing 3M electronic fluorinated liquid 7200, monofunctional perfluoropolyether (methyl)acrylate (M_{w}≈500, SuZhou Chemwells Advanced Materials CO., LTD.), and p-hydroxyanisole at a weight ratio of 5:5:0.025, and was vaporized at a vaporization temperature of 90° C. and then the gas was introduced into the plasma chamber at a flow rate of 150 μL/min. The pressure in the chamber was maintained at 20 mTorr, the flow rate of helium gas was maintained at 100 sccm, and a radio frequency plasma discharge was turned on to carry out plasma chemical vapor deposition on the surface of the substrate. The energy output mode of radio frequency was pulse, in which the pulse duty cycle was 50%, the pulse frequency was 250 Hz, the pulse discharge power was 180 W, and the reaction time was 3600 s.

After coating, compressed air was introduced to restore the chamber to normal pressure, and the coated substrate was taken out. The water contact angle and the oil contact angle were tested, and the test results are listed in the following Table 1.

### Embodiment 2

A Si sheet serving as a substrate was placed on a substrate holder in a plasma chamber, the chamber was vacuumized to reach a pressure of 20 mTorr, helium gas was introduced at a flow rate of 100 sccm, and a temperature of the chamber was 50° C.

A pressure in the chamber was maintained at 20 mTorr, the flow rate of helium gas was maintained at 100 sccm, and a plasma continuous discharge was turned on to pretreat the substrate. The discharge power was 100 W, and the discharge duration time was 600 s.

Thereafter, a homogeneous solution was prepared by mixing 3M electronic fluorinated liquid 7200, monofunctional perfluoropolyether (methyl)acrylate (M_{w}≈1000, SuZhou Chemwells Advanced Materials CO., LTD.), and p-hydroxyanisole at a weight ratio of 5:5:0.025, and was vaporized at a vaporization temperature of 110° C. and then the gas was introduced into the plasma chamber at a flow rate of 150 μL/min. The pressure in the chamber was maintained at 20 mTorr, the flow rate of helium gas was maintained at 100 sccm, and a radio frequency plasma discharge was turned on to carry out plasma chemical vapor deposition on the surface of the substrate. The energy output mode of radio frequency was pulse, in which the pulse duty cycle was 50%, the pulse frequency was 250 Hz, the pulse discharge power was 180 W, and the reaction time was 3600 s.

After coating, compressed air was introduced to restore the chamber to normal pressure, and the coated substrate was taken out. The water contact angle and the oil contact angle were tested, and the test results are listed in the following Table 1.

### Embodiment 3

A Si sheet serving as a substrate was placed on a substrate holder in a plasma chamber, the chamber was vacuumized to reach a pressure of 20 mTorr, helium gas was introduced at a flow rate of 100 sccm, and a temperature of the chamber was 50° C.

A pressure in the chamber was maintained at 20 mTorr, the flow rate of helium gas was maintained at 100 sccm, and a plasma continuous discharge was turned on to pretreat the substrate. The discharge power was 100 W, and the discharge duration time was 600 s.

Thereafter, a homogeneous solution was prepared by mixing 3M electronic fluorinated liquid 7200, monofunctional perfluoropolyether (methyl)acrylate (M_{w}≈2000, SuZhou Chemwells Advanced Materials CO., LTD.), and p-hydroxyanisole at a weight ratio of 5:5:0.025, and was vaporized at a vaporization temperature of 110° C. and then the gas was introduced into the plasma chamber at a flow rate of 150 μL/min. The pressure in the chamber was maintained at 20 mTorr, the flow rate of helium gas was maintained at 100 sccm, and a radio frequency plasma discharge was turned on to carry out plasma chemical vapor deposition on the surface of the substrate. The energy output mode of radio frequency was pulse, in which the pulse duty cycle was 50%, the pulse frequency was 250 Hz, the pulse discharge power was 180 W, and the reaction time was 3600 s.

After coating, compressed air was introduced to restore the chamber to normal pressure, and the coated substrate was taken out. The water contact angle and the oil contact angle were tested, and the test results are listed in the following Table 1.

### Comparative Embodiment 1

A Si sheet serving as a substrate was placed on a substrate holder in a plasma chamber, the chamber was vacuumized to reach a pressure of 20 mTorr, helium gas was introduced at a flow rate of 100 sccm, and a temperature of the chamber was 50° C.

A pressure in the chamber was maintained at 20 m Torr, the flow rate of helium gas was maintained at 100 sccm, and a plasma continuous discharge was turned on to pretreat the substrate. The discharge power was 100 W, and the discharge duration time was 600 s.

Thereafter, a homogeneous solution was prepared by mixing 3M electronic fluorinated liquid 7200, bifunctional perfluoropolyether (methyl)acrylate (M_{w}≈2000, Solvay Fluorolink® MD700), and p-hydroxyanisole at a weight ratio of 5:5:0.025, and was vaporized at a vaporization temperature of 110° C. and then the gas was introduced into the plasma chamber at a flow rate of 150 μL/min. The pressure in the chamber was maintained at 20 mTorr, the flow rate of helium gas was maintained at 100 sccm, and a radio frequency plasma discharge was turned on to carry out plasma chemical vapor deposition on the surface of the substrate. The energy output mode of radio frequency was pulse, in which the pulse duty cycle was 50%, the pulse frequency was 250 Hz, the pulse discharge power was 180 W, and the reaction time was 3600 s.

After coating, compressed air was introduced to restore the chamber to normal pressure, and the coated substrate was taken out. The water contact angle and the oil contact angle were tested, and the test results are listed in the following Table 1.

### Embodiment 4

A Si sheet serving as a substrate was placed on a substrate holder in a plasma chamber, the chamber was vacuumized to reach a pressure of 20 mTorr, helium gas was introduced at a flow rate of 100 sccm, and a temperature of the chamber was 50° C.

A pressure in the chamber was maintained at 20 mTorr, the flow rate of helium gas was maintained at 100 sccm, and a plasma continuous discharge was turned on to pretreat the substrate. The discharge power was 120 W, and the discharge duration time was 600 s.

Thereafter, a homogeneous solution was prepared by mixing 3M electronic fluorinated liquid 7300, monofunctional perfluoropolyether (methyl)acrylate (M_{w}≈500, SuZhou Chemwells Advanced Materials CO., LTD.), and 2,6-di-tert-butyl-p-cresol at a weight ratio of 3:7:0.015, and was vaporized at a vaporization temperature of 90° C. and then the gas was introduced into the plasma chamber at a flow rate of 120 μL/min. The pressure in the chamber was maintained at 20 mTorr, the flow rate of helium gas was maintained at 100 sccm, and a radio frequency plasma discharge was turned on to carry out plasma chemical vapor deposition on the surface of the substrate. The energy output mode of radio frequency was pulse, in which the pulse duty cycle was 25%, the pulse frequency was 200 Hz, the pulse discharge power was 200 W, and the reaction time was 7200 s.

After coating, compressed air was introduced to restore the chamber to normal pressure, and the coated substrate was taken out. The water contact angle and the oil contact angle were tested, and the test results are listed in the following Table 1.

### Embodiment 5

A Si sheet serving as a substrate was placed on a substrate holder in a plasma chamber, the chamber was vacuumized to reach a pressure of 20 mTorr, helium gas was introduced at a flow rate of 150 sccm, and a temperature of the chamber was 50° C.

A pressure in the chamber was maintained at 20 m Torr, the flow rate of helium gas was maintained at 150 sccm, and a plasma continuous discharge was turned on to pretreat the substrate. The discharge power was 120 W, and the discharge duration time was 600 s.

Thereafter, a homogeneous solution was prepared by mixing 3M electronic fluorinated liquid 7500, monofunctional perfluoropolyether (methyl)acrylate (M_{w}≈500, SuZhou Chemwells Advanced Materials CO., LTD.), and hydroquinone at a weight ratio of 7:3:0.042, and was vaporized at a vaporization temperature of 90° C. and then the gas was introduced into the plasma chamber at a flow rate of 180 μL/min. The pressure in the chamber was maintained at 20 m Torr, the flow rate of helium gas was maintained at 150 sccm, and a radio frequency plasma discharge was turned on to carry out plasma chemical vapor deposition on the surface of the substrate. The energy output mode of radio frequency was pulse, in which the pulse duty cycle was 35%, the pulse frequency was 100 Hz, the pulse discharge power was 300 W, and the reaction time was 3600 s.

After coating, compressed air was introduced to restore the chamber to normal pressure, and the coated substrate was taken out. The water contact angle and the oil contact angle were tested, and the test results are listed in the following Table 1.

TABLE 1
Test Results of the water contact angle and the oil contact angle

| | Water | Oil (n-hexadecane) |
|---|---|---|
| | contact angle | contact angle |
| Embodiment 1 | 109° | 63° |
| Embodiment 2 | 115° | 69° |
| Embodiment 3 | 121° | 73° |
| Comparative Embodiment 1 | 108° | 62° |
| Embodiment 4 | 110° | 64° |
| Embodiment 5 | 112° | 65° |

According to the test results in Table 1, a comparison of Embodiment 1, Embodiment 2, and Embodiment 3 demonstrates that the increased molecular weight of the monofunctional perfluoropolyether (meth)acrylate leads to increased water contact angle and increased oil contact angle, indicating excellent hydrophobic and oleophobic properties.

According to the test results in Table 1, referring to Embodiment 3 and Comparative Embodiment 1, compared to the film layer prepared from bifunctional perfluoropolyether (meth)acrylate monomer, the film layer prepared from monofunctional perfluoropolyether (meth)acrylate monomer with the same molecular weight has a greater water contact angle and a greater oil contact angle, and thus exhibits better hydrophobicity and oleophobicity.

According to the test results in Table 1, in Embodiment 1, Embodiment 4, and Embodiment 5, the fluorocarbon solutions and the polymerization inhibitors are respectively different, the monomers are the same, and the film layers prepared under controlled conditions of different plasma discharge parameters and flow rates of the monomer all exhibited excellent hydrophobic and oleophobic properties.

The aforementioned descriptions are merely exemplary embodiments provided to illustrate the principles of the present disclosure and are not intended to limit its scope of protection. Any modifications and improvements that may be made by those skilled in the art without departing from the spirit and essence of the present disclosure shall also fall within the protection scope of the present disclosure.

1. A hydrophobic and oleophobic film layer, being a plasma polymerization film layer formed by contacting a substrate with a plasma of a monomer having a structure of formula (1), 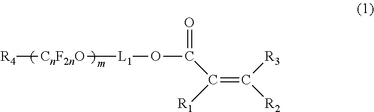
in formula (1), R₁, R₂ and R³ are respectively and independently selected from a C₁-C₄ hydrocarbon group or a hydrogen atom; R₄ is selected from a C₁-C₄ perfluorinated alkyl group or a fluorine atom; and L₁ is a linking group; and
m is an integer greater than or equal to 1; and each n in the m number of repeating units is respectively and independently selected from integers greater than or equal to 1.

2. The hydrophobic and oleophobic film layer according to claim 1, wherein in formula (1), the R₁, R₂ and R³ are respectively and independently selected from a methyl group or a hydrogen atom.

3. The hydrophobic and oleophobic film layer according to claim 1, wherein in formula (1), the R; is a methyl group, and the R₂ and R₅ are hydrogen atoms.

4. The hydrophobic and oleophobic film layer according to claim 1, wherein a weight-average molecular weight of the monomer having the structure of formula (1) is greater than or equal to 500.

5. The hydrophobic and oleophobic film layer according to claim 4, wherein the weight-average molecular weight of the monomer having the structure of formula (1) is greater than or equal to 1000.

6. The hydrophobic and oleophobic film layer according to claim 1, wherein in formula (1), the L₁ is selected from a substituted C₁-C₄ alkylene group or an unsubstituted C₁-C₄ alkylene group.

7. The hydrophobic and oleophobic film layer according to claim 6, wherein a substituent of the substituted C₁-C₄ alkylene group comprises one or more selected from a group consisting of: alkyl, cycloalkyl, alkenyl, alkynyl, aryl, heteroaryl, heterocyclic group, carboxyl, carboxylate ion, carboxylic ester group, carbamate group, alkoxy, ketone group, aldehyde group, amine group, amide group, hydroxyl, nitrile group, nitroso group, and halogen.

8. The hydrophobic and oleophobic film layer according to claim 7, wherein in formula (1), the L₁ is a perfluorinated alkylene group.

9. The hydrophobic and oleophobic film layer according to claim 1, wherein the monomer of formula (1) has a structure of formula (2), 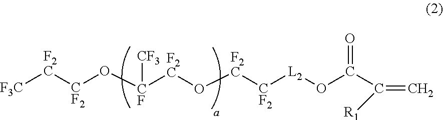
in formula (2), a is an integer greater than or equal to 1; and L₂ is selected from a connecting bond, a substituted methylene group or an unsubstituted methylene group, or a substituted ethylene group or an unsubstituted ethylene group.

10. The hydrophobic and oleophobic film layer according to claim 1, wherein the monomer of formula (1) has a structure of formula (3), 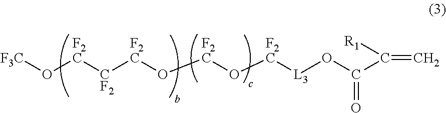
in formula (3), b is an integer greater than or equal to 1, c is an integer greater than or equal to 1, and L₃ is selected from a connecting bond, or a substituted C₁-C₃ alkylene group or an unsubstituted C₁-C₃ alkylene group.

11. The hydrophobic and oleophobic film layer according to claim 1, wherein the monomer of formula (1) has a structure of formula (4), 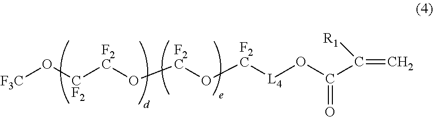
in formula (4), d is an integer greater than or equal to 1, e is an integer greater than or equal to 1, and L₄ is selected from a connecting bond, or a substituted C₁-C₃ alkylene group or an unsubstituted C₁-C₃ alkylene group.

12. The hydrophobic and oleophobic film layer according to claim 1, wherein the monomer of formula (1) has a structure of formula (5), 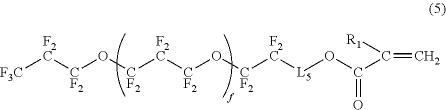
in formula (5), f is an integer greater than or equal to 1; and L₅ is selected from a connecting bond, a substituted methylene group or an unsubstituted methylene group, or a substituted ethylene group or an unsubstituted ethylene group.

13. The hydrophobic and oleophobic film layer according to claim 1, wherein a water contact angle of the hydrophobic and oleophobic film layer is greater than or equal to 110°, and an n-hexadecane contact angle of the hydrophobic and oleophobic film layer is greater than or equal to 65°.

14. A method for preparing the hydrophobic and oleophobic film layer according to claim 1, comprising:
placing a substrate in a plasma reaction chamber; and
dissolving and then adding the monomer having the structure of formula (1), a fluorine-containing solvent and a polymerization inhibitor into a monomer tank, vaporizing and then introducing the monomer into the plasma reaction chamber, turning on a plasma discharge, and forming the hydrophobic and oleophobic film layer on a surface of the substrate from the monomer through chemical vapor deposition.

15. The method according to claim 14, wherein a weight-mass ratio of the monomer to the fluorine-containing solvent ranges from 1:9 to 9:1, and a mass of the polymerization inhibitor ranges from 0.1% to 1% of a mass of the monomer.

16. The method according to claim 14, wherein the fluorine-containing solvent is a fluorocarbon solvent, and the fluorocarbon solvent comprises one or more selected from a group consisting of: methyl perfluorobutyl ether, ethyl perfluorobutyl ether, 3-methoxyperfluorohexane, perfluorobutyl ethyl propyl ether, perfluoropolyether oil, hexafluoropropylene oxide dimer, hexafluoropropylene oxide trimer, perfluorotriethylamine, perfluorotripropylamine, perfluorotributylamine, 3M electronic fluorinated liquid 7100, 3M electronic fluorinated liquid 7200, 3M electronic fluorinated liquid 7300, 3M electronic fluorinated liquid 7500, and 3M electronic fluorinated liquid 7700.

17. (canceled)

18. The method according to claim 14, wherein the polymerization inhibitor comprises one or more selected from a group consisting of: hydroquinone, p-benzoquinone, methyl hydroquinone, p-hydroxyanisole, 2-tert-butylhydroquinone, 2,5-di-tert-butylhydroquinone, and 2,6-di-tert-butyl-p-cresol.

19. The method according to claim 14, wherein a gas vaporized from the monomer is introduced into the plasma reaction chamber at a flow rate ranging from 10 μL/min to 2000 μL/min.

20. The method according to claim 14, wherein the plasma discharge is a continuous discharge, a discharge power ranges from 10W to 300W, and a discharge duration time ranges from 60 s to 36000 s; or
wherein the plasma discharge is a pulse discharge, a discharge power ranges from 10W to 400W, a pulse duty cycle ranges from 0.1% to 80%, a pulse frequency ranges from 10 Hz to 500 Hz, and a discharge duration time ranges from 200 s to 36000 s.

21-23. (canceled)

24. A device, wherein at least a part of a surface of the device is provided with the hydrophobic and oleophobic film layer according to claim 1.
